(19) United States
(12) Patent Application Publication
(10) Pub. No.: US 2022/0325140 A1
(43) Pub. Date: Oct. 13, 2022

(54) COMPOSITION FOR SURFACE TREATMENT, SURFACE TREATMENT METHOD, AND METHOD FOR PRODUCING SEMICONDUCTOR SUBSTRATE

(71) Applicant: Fujimi Incorporated, Kiyosu-shi (JP)

(72) Inventors: Tsutomu YOSHINO, Kiyosu-shi (JP); Yoshihiro IZAWA, Kiyosu-shi (JP); Yasuto ISHIDA, Kiyosu-shi (JP)

(73) Assignee: Fujimi Incorporated, Kiyosu-shi (JP)

(21) Appl. No.: 17/707,003

(22) Filed: Mar. 29, 2022

(30) Foreign Application Priority Data
Mar. 31, 2021 (JP) 2021-059480

(51) Int. Cl. C09G 1/16; H01L 21/306

(52) U.S. Cl. CPC C09G 1/16; H01L 21/30625

(57) ABSTRACT

Provided is a means capable of sufficiently removing residues remaining on a surface of a polished object. Provided is a composition for surface treatment for use in reducing a residue on a surface of a polished object, containing a solvent and a water-soluble polymer, wherein an adsorption amount of the water-soluble polymer adsorbed to a quartz crystal microbalance electrode is 100 ng/cm² or more and 600 ng/cm² or less per unit area of the quartz crystal microbalance electrode.

### CROSS-REFERENCE TO RELATED APPLICATION

The entire disclosure of Japanese Patent Application No. 2021-059480, filed on Mar. 31, 2021, is incorporated herein by reference in its entirety.

### TECHNICAL FIELD

The present invention relates to a composition for surface treatment, a surface treatment method, and a method for producing a semiconductor substrate.

### BACKGROUND ART

In recent years, a so-called chemical mechanical polishing (CMP) technique for physically polishing and flattening a semiconductor substrate in producing a device is used in accordance with multilayer wiring on a surface of a semiconductor substrate. CMP is a method for flattening a surface of an object to be polished (polishing object) such as a semiconductor substrate using a polishing composition (slurry) containing abrasive grains such as silica, alumina, or ceria, an anti-corrosion agent, a surfactant, or the like. The object to be polished (polishing object) is silicon, polysilicon, silicon oxide, silicon nitride, a wiring or a plug which consists of metal, or the like.

On a surface of a semiconductor substrate after the CMP step, impurities (also referred to as foreign matter or residues) remain in a large amount. Impurities include abrasive grains, metals, an anti-corrosion agent and organic matter such as a surfactant, which are derived from a polishing composition used for CMP, a silicon-containing material or a metal which is generated by polishing of a silicon-containing material, metal wiring, a plug or the like as an object to be polished, and also organic matter such as pad debris which is generated from various pads.

Once a surface of a semiconductor substrate is contaminated with these impurities, the electrical properties of the semiconductor may be adversely affected, so as to lower device reliability. Hence, it is desired to remove these impurities from the surface of a semiconductor substrate by introducing a cleaning step following the CMP step.

As such a cleaning composition, for example, Japanese Patent Laid-Open No. 2012-74678 (corresponding to U.S. Patent Application Publication No. 2013/0174867) discloses a cleaning composition for cleaning a semiconductor substrate, which contains polycarboxylic acid or hydroxycarboxylic acid, a sulfonic acid-type anionic surfactant, a carboxylic acid-type anionic surfactant, and water, whereby foreign matter can be removed without corroding a surface of a substrate.

### SUMMARY OF THE INVENTION

### Technical Problem

However, the technology of Japanese Patent Laid-Open No. 2012-74678 is problematic in that foreign matter (residues) cannot be sufficiently removed from a polished object by the cleaning.

Therefore, an object of the present invention is to provide a means capable of sufficiently removing residues remaining on a surface of a polished object.

### Solution to Problem

The inventors of the present invention have intensively studied in view of the above problem. As a result, the inventors have discovered that the above problem is solved by a composition for surface treatment, whereby a water-soluble polymer can be adsorbed in a specific range of amount to a quartz crystal microbalance electrode, and thus have completed the present invention.

Specifically, the present invention is a composition for surface treatment for use in reducing a residue on a surface of a polished object, containing a solvent and a water-soluble polymer, wherein an adsorption amount of the above water-soluble polymer adsorbed to a quartz crystal microbalance electrode is 100 ng/cm² or more and 600 ng/cm² or less per unit area of the above quartz crystal microbalance electrode.

### DESCRIPTION OF EMBODIMENTS

The present invention is a composition for surface treatment for use in reducing a residue on a surface of a polished object, containing a solvent and a water-soluble polymer, wherein an adsorption amount of the above water-soluble polymer adsorbed to a quartz crystal microbalance electrode is 100 ng/cm² or more and 600 ng/cm² or less per unit area of the above quartz crystal microbalance electrode. According to such a composition for surface treatment of the present invention, residues remaining on a surface of a polished object can be sufficiently removed.

The inventors of the present invention infer the mechanism of removing residues on a surface of a polished object with such configuration, as follows.

Specifically, the fact that the adsorption amount of a water-soluble polymer contained in a composition for surface treatment, which is adsorbed to a quartz crystal microbalance electrode, is 100 ng/cm² or more and 600 ng/cm² or less per unit area of the quartz crystal microbalance electrode means that the water-soluble polymer is adsorbed in an appropriate amount to a surface of a polished object. This can prevent the re-adhesion of residues (contaminants) to the surface of the polished object. Moreover, if the adsorption amount of the water-soluble polymer is within the above range, the water-soluble polymer itself will almost never or will never remain as a residue, the water-soluble polymer will be easily desorbed from the surface of the polished object, so that residues can be sufficiently removed.

Note that the above mechanism is based on the inference, and the present invention is not limited by the above mechanism.

The embodiments of the present invention will be described in detail as follows, but the present invention is not limited to the following embodiments alone. Throughout the present specification, unless particularly stated otherwise, any expression in a singular form should be understood to encompass the concept of its plural form. Therefore, unless particularly stated otherwise, the article specifying a single form (for example, “a”, “an”, “the”, and the like in the case of English language) should be understood to encompass the concept of its plural form. Furthermore, unless particularly stated otherwise, any term used in the present specification should be understood as a term that is used to have the meaning conventionally used in the relevant technical field. Therefore, unless defined otherwise, all the technical terms and scientific terms used in the present specification have the same meaning as generally understood by a person ordinarily skilled in the art to which the present invention is pertained. If there is any conflict in meaning, the present specification (including the definitions) takes priority. In addition, in this specification, unless otherwise specified, operation and measurement of physical properties, etc., are performed under conditions of room temperature (20° C. or higher and 25° C. or lower)/relative humidity of 40% RH or more and 50% RH or less.

<Residue>

The term “residue(s)” used herein refers to foreign matter adhered to a surface of a polished object. Examples of a residue include, but are not particularly limited to, later-described organic residues, particle residues derived from abrasive grains contained in a polishing composition, residues composed of components other than particle residues, and organic residues, and other residues such as mixtures of particle residues and organic residues.

The total number of residues represents the total number of all residues regardless the types. The total number of residues can be measured using a wafer defect inspection apparatus. A method for measuring the number of residues is described in detail in the following Examples.

The term “organic residue(s)” used herein represents, among foreign matter adhered to a surface of a polished object (object to be subjected to surface treatment), components comprising organic matters, organic salts, and the like such as organic low molecular weight compounds and polymer compounds.

Examples of organic residues adhered to a polished object include pad debris that are generated from pads used in later-described polishing step or rinse polishing step, or components derived from additives contained in polishing compositions that are used in the polishing step or compositions for surface treatment used in the rinse polishing step.

Note that since organic residues and other foreign matter are significantly different from each other in terms of color and shape, whether or not the foreign matter is an organic residue can be visually confirmed by SEM observation. Whether or not foreign matter is an organic residue can be determined as necessary by elementary analysis using energy-dispersive X-ray spectroscopy (EDX). The number of organic residues can be measured using a wafer defect inspection apparatus and SEM or EDX elementary analysis.

<Polished Object (the Polishing Object that has been Polished)>

The term “polished object” used herein refers to an object to be polished that has been polished in a polishing step. The polishing step is not particularly limited, but is preferably a CMP step.

Examples of materials contained in an object to be polished according to the present invention include, but are not particularly limited to, silicon oxide, silicon nitride, silicon carbonitride (SiCN), polycrystalline silicon (polysilicon), non-crystalline silicon (amorphous silicon), metal and SiGe.

Examples of a silicon oxide-containing film include a TEOS (Tetraethyl Orthosilicate)-type silicon oxide film (hereinafter may also be simply referred to as “TEOS film”) that is formed using tetraethyl orthosilicate as a precursor, an HDP (High Density Plasma) film, an USG (Undoped Silicate Glass) film, a PSG (Phosphorus Silicate Glass) film, a BPSG (Boron-Phospho Silicate Glass) film, and an RTO (Rapid Thermal Oxidation) film. Materials contained in an object to be polished may be of only one type or of two or more types in combination.

The polished object is preferably a polished semiconductor substrate, and is more preferably a semiconductor substrate after the CMP step. The reason for this is that residues can break a semiconductor device. When a polished object is a polished semiconductor substrate, a step for cleaning the semiconductor substrate is required to be able to remove residues as far as possible.

Further, the composition for surface treatment according to an embodiment of the present invention is suitably used for reducing residues on a surface of a polished object containing both a hydrophilic material and a hydrophobic material. Here, the term “hydrophilic material” refers to a material having a contact angle with respect to water of less than 50°, and the term “hydrophobic material” refers to a material having a contact angle with respect to water of 50° or more. Note that the contact angle with respect to water is a value measured using a contact angle meter, Drop Master (manufactured by Kyowa Interface Science Co., Ltd., DMo-501).

Specific examples of the hydrophilic material include silicon oxide, silicon nitride, silicon oxynitride, tungsten, titanium nitride, tantalum nitride, and boron-containing silicon. These hydrophilic materials may be used singly or in combinations of two or more thereof. Further, specific examples of the hydrophobic material include polycrystalline silicon, single crystal silicon, non-crystalline silicon, and carbon-containing silicon. These hydrophobic materials may be used singly or in combinations of two or more thereof. According to a preferred embodiment of the present invention, the hydrophilic material is silicon oxide and the hydrophobic material is polycrystalline silicon.

<Composition for Surface Treatment>

The composition for surface treatment according to the present invention contains a water-soluble polymer. The term “water-soluble polymer” used herein refers to a water-soluble polymer having the same (homopolymer) or different repeating constitutional units (different from each other) (copolymer), which can be typically a compound having a weight-average molecular weight (Mw) of 1000 or more. The type of a polymer used as such a water-soluble polymer is not particularly limited, and any of anionic, cationic, nonionic, and amphoteric polymers can also be used herein. Further, the form of a copolymer when a water-soluble polymer is the copolymer may be any of a block copolymer, a random copolymer, a graft copolymer, and an alternating copolymer.

Examples of the anionic water-soluble polymer include polyvinyl sulfonic acid, polystyrene sulfonic acid, polyallyl sulfonic acid, polymethallyl sulfonic acid, poly(2-acrylamido-2-methylpropanesulfonic acid), polyisoprene sulfonic acid, polyacrylic acid, and polymethacrylic acid.

Examples of the cationic water-soluble polymer include polyethylenimine (PEI), polyvinyl amine, polyallyl amine, polyvinyl pyridine, and cationic acrylamide polymers. Specifically, for example, poly-diallyl dimethyl ammonium chloride and the like can be used.

Examples of the nonionic water-soluble polymer include water-soluble polysaccharides such as polyvinyl alcohol, polyvinyl pyrrolidone, polyacrylamide, poly-N-vinylacetamide, polyamines, polyvinyl ethers (polyvinyl methyl ether, polyvinyl ethyl ether, polyvinyl isobutyl ether, etc.), polyalkylene oxides (polyethylene oxide, polypropylene oxide etc.), polyglycerol, polyethylene glycol, polypropylene glycol, and hydroxyethylcellulose, alginic acid polyhydric alcohol ester, water soluble urea resin, dextrin derivative, and casein. Furthermore, not only those having such main chain structures, but also graft copolymers having nonionic polymer structures in the side chains can also be suitably used.

Examples of the water-soluble amphoteric polymer include a copolymer of a vinyl monomer having an anionic group and a vinyl monomer having a cationic group, and an amphoteric vinyl polymer having a carboxybetaine group or a sulfobetaine group. Specific examples thereof include an acrylic acid/dimethylaminoethyl methacrylic acid copolymer, and an acrylic acid/diethylaminoethyl methacrylic acid copolymer.

Moreover, copolymers of the above-exemplified water-soluble polymers can also be used.

Such water-soluble polymers can be used singly or in combinations of two or more thereof. Further, as the water-soluble polymers, commercial products thereof or synthetic products thereof may also be used.

Of these water-soluble polymers, from the viewpoints of retaining water molecules by hydrogen bonding, and better adsorption to a substrate because of hydrophobic interaction, a nonionic water-soluble polymer is preferable. Furthermore, as nonionic water-soluble polymers, polyvinyl alcohol, poly-N-vinylacetamide, hydroxyethylcellulose, polyvinyl pyrrolidone, polyglycerol, polyethylene glycol, and polypropylene glycol are more preferable, and poly-N-vinylacetamide is further preferable.

The lower limit of the weight-average molecular weight (Mw) of the water-soluble polymer is preferably 1,000 or more, more preferably 1,500 or more, and further preferably 2,000 or more. Further, the upper limit of the weight-average molecular weight (Mw) of the water-soluble polymer is preferably 1,500,000 or less, more preferably 1,300,000 or less, and further preferably 1,000,000 or less. Note that the weight-average molecular weight (Mw) of the water-soluble polymer can be measured as a value in terms of polyethylene glycol by gel permeation chromatography (GPC).

<Solubility Parameter of Water-Soluble Polymer>

The water-soluble polymer has a solubility parameter (SP value) of preferably more than 10 and less than 19, and more preferably 11 or more and 15 or less. When the SP value is more than 10, the resulting solubility to water that is mainly used as a solvent will increase and the water-soluble polymer will be difficult to remain as a residue on a surface of a polished object. As the SP value of the water-soluble polymer increases, the adsorption amount of the water-soluble polymer adsorbed to a quartz crystal microbalance electrode tends to decrease. Further, when the SP value is less than 19, solubility to water that is mainly used as a solvent tends to decrease, and the water-soluble polymer will be easily adsorbed to a surface of a polished object, even more increasing the effect of preventing the re-adhesion of a residue to the surface of the polished object. As the SP value of the water-soluble polymer decreases, the adsorption amount of the water-soluble polymer adsorbed to a quartz crystal microbalance electrode tends to increase.

Note that the SP value of the water-soluble polymer, which is used herein, is a value calculated by a Fedors method (Literature: R. F. Fedors, Polym. Eng. Sci., 14[2]147 (1974)).

The content of a water-soluble polymer in a composition for surface treatment is set appropriately in accordance with the type of the water-soluble polymer to be used. The lower limit of the content is, on the basis of the total mass of a composition for surface treatment of 100 mass %, preferably 0.01 mass % or more, more preferably 0.05 mass % or more, and further preferably 0.1 mass % or more. Further, the upper limit of the content of a water-soluble polymer in a composition for surface treatment is, on the basis of the total mass of the composition for surface treatment of 100 mass %, preferably 1 mass % or less, more preferably 0.5 mass % or less, and further preferably 0.2 mass % or less.

Note that when a composition for surface treatment contains two or more types of water-soluble polymers, the content of the water-soluble polymers is intended to mean the total amount of these types of water-soluble polymers.

<Adsorption Amount of Water-Soluble Polymer>

The composition for surface treatment according to the present invention contains water-soluble polymer(s), wherein the adsorption amount of the water-soluble polymer(s) adsorbed to a quartz crystal microbalance electrode is 100 ng/cm² or more and 600 ng/cm² or less per unit area of the quartz crystal microbalance electrode. The adsorption amount of water-soluble polymer(s) adsorbed to a quartz crystal microbalance electrode is a good indicator of the adsorption amount of the water-soluble polymer(s) adsorbed to a surface of a polished object. When the amount thereof adsorbed to the quartz crystal microbalance electrode is within the above range, residues remaining on the surface of the polished object can be sufficiently removed.

A quartz resonator has a sensitivity with which nanogram orders of mass can be measured. A quartz resonator has a structure where the surfaces on both sides of a slice prepared by cutting quartz crystal in a thin plate are sandwiched by metal electrodes. Alternating electric field applied to the metal electrodes on both sides results in oscillation at a constant frequency (resonance frequency) due to reverse voltage drop in crystal. When substances are adsorbed in a trace amount onto the metal electrodes, resonance frequency decreases in proportion to the adsorption amount. Through the use of this phenomenon, a quartz resonator can be used as a microbalance.

The amount of a change in the frequency of a quartz resonator and the mass of substances adsorbed on metal electrodes are calculated according to the following Sauerbrey formula (formula a).

$$\begin{matrix}[ Equation 1 ] & \\ Δ F = \frac{- 2 {F}_{0}^{2}}{\sqrt{{ρ}_{Q} {μ}_{Q}}} \cdot \frac{Δ m}{A} & ( formula a )\end{matrix}$$

In the above formula a, ΔF denotes frequency change amount, Δm denotes mass change amount, F₀ denotes fundamental frequency, ρ_{Q} denotes density of crystal, μₖ denotes shearing stress of crystal and A denotes electrode area. The measurement method is also referred to as a quartz resonator microbalance (Quartz Crystal Microbalance: QCM) method.

Quartz crystal microbalance electrode types vary. However, as an indicator of the adsorption amount of a water-soluble polymer adsorbed to a hydrophilic material contained in a polished object, in the present invention, the adsorption amount of the water-soluble polymer is preferably measured using an SiO₂ (silicon oxide) electrode. Further, as an indicator of the adsorption amount of a water-soluble polymer adsorbed to a hydrophobic material contained in a polished object, the adsorption amount of the water-soluble polymer is preferably measured using an Au (gold) electrode. Through selection of such electrodes, the adsorption amount thereof to a quartz crystal microbalance electrode can be a better indicator of the adsorption amount of a water-soluble polymer that is adsorbed to a surface of a polished object containing a hydrophilic material and a hydrophobic material.

As described above, in the present invention, the adsorption amount of a water-soluble polymer adsorbed to a quartz crystal microbalance electrode is 100 ng/cm² or more and 600 ng/cm² or less per unit area of the quartz crystal microbalance electrode. The adsorption amount of less than 100 ng/cm² results in a decreased amount of a water-soluble polymer adsorbed to a surface of a polished object, lowering the effect of preventing re-adhesion of residues to the surface of the polished object. On the other hand, the adsorption amount of more than 600 ng/cm² results in an increased amount of a water-soluble polymer adsorbed to a surface of a polished object, and thus the water-soluble polymer itself will remain more easily as a residue on the surface of the polished object.

The composition for surface treatment according to the present invention exhibits the above-described adsorption amount of a water-soluble polymer for both the SiO₂ electrode and the Au electrode. Specifically, the composition for surface treatment according to the present invention exhibits the adsorption amount of a water-soluble polymer suitable for removing residues for both the hydrophilic material and the hydrophobic material.

When the quartz crystal microbalance electrode is a SiO₂ electrode, the lower limit of the adsorption amount of a water-soluble polymer per unit area of the quartz crystal microbalance electrode is preferably 150 ng/cm² or more, and more preferably 200 ng/cm² or more. Further, the upper limit of the adsorption amount of a water-soluble polymer per unit area of the quartz crystal microbalance electrode is preferably 500 ng/cm² or less and more preferably 450 ng/cm² or less.

When the quartz crystal microbalance electrode is an Au electrode, the lower limit of the adsorption amount of a water-soluble polymer per unit area of the quartz crystal microbalance electrode is preferably 150 ng/cm² or more and more preferably 200 ng/cm² or more. Further, the upper limit of the adsorption amount of a water-soluble polymer per unit area of the quartz crystal microbalance electrode is preferably 500 ng/cm² or less and more preferably 400 ng/cm² or less.

The adsorption amount of a water-soluble polymer per unit area of the quartz crystal microbalance electrode can be set by appropriately selecting the type of the water-soluble polymer, the content of the water-soluble polymer in the composition for surface treatment, the SP value of the water-soluble polymer, the pH of the composition for surface treatment, and the like. For example, when the SP value of the water-soluble polymer is decreased, the adsorption amount tends to increase. For example, when the content of the water-soluble polymer in the composition for surface treatment is increased, the adsorption amount tends to increase.

Note that a detailed method for measuring the adsorption amount of a water-soluble polymer is as described in Examples.

<Surfactant>

The composition for surface treatment according to the present invention may further contain a surfactant from the viewpoint of further improving the effects of the present invention. The type of a surfactant is not particularly limited and may be any of nonionic, anionic, cationic and amphoteric surfactants.

Examples of a nonionic surfactant include an alkyl ether type such as polyoxyethylene lauryl ether and polyoxyethylene oleyl ether; an alkyl phenyl ether type such as polyoxyethylene octyl phenyl ether; an alkyl ester type such as polyoxyethylene laurate; an alkylamine type such as polyoxyethylene lauryl amino ether; an alkylamide type such as polyoxyethylene lauramide; a polypropylene glycol ether type such as polyoxyethylene polyoxypropylene ether; an alkanolamide type such as oleic acid diethanolamide; and an allyl phenyl ether type such as polyoxyalkylene allyl phenyl ether. In addition to these examples, propylene glycol, diethylene glycol, monoethanolamine, alcohol ethoxylate, alkylphenol ethoxylate, tertiary acetylene glycol, alkanolamide or the like can also be used as a nonionic surfactant.

Examples of an anionic surfactant include a carboxylic acid type such as sodium myristate, sodium palmitate, sodium stearate, sodium laurate, and potassium laurate; a sulfuric acid ester type such as sodium octylsulfonate; a phosphoric acid ester type such as lauryl phosphate, and sodium lauryl phosphate; and a sulfonic acid type such as dioctyl sulfosuccinate sodium, and sodium dodecylbenzenesulfonate.

Examples of a cationic surfactant include amines such as laurylamine hydrochloride; quaternary ammonium salts such as polyethoxyamine, and lauryltrimethylammonium chloride; and pyridinium salts such as laurylpyridinium chloride.

Examples of an amphoteric surfactant include alkyl betaines or sulfobetaines such as lecithin, alkylamine oxide, and N-alkyl-N,N-dimethyl ammonium betaine.

The surfactants may be used singly or in combinations of two or more thereof. Further, as a surfactant, a commercial product thereof or a synthetic product thereof may also be used.

When the composition for surface treatment contains a surfactant, the lower limit of the content of the surfactant is preferably 0.01 mass % or more, and more preferably 0.05 mass % or more on the basis of the total mass of the composition for surface treatment of 100 mass %. Further, the upper limit of the content of the water-soluble polymer in the composition for surface treatment is preferably 5 mass % or less and more preferably 1 mass % or less on the basis of the total mass of the composition for surface treatment of 100 mass %.

Note that when the composition for surface treatment contains two or more types of surfactant, the content of surfactants is intended to be the total amount of these types of surfactant.

<Solvent>

The composition for surface treatment according to the present invention contains a solvent. A solvent has a function of dispersing or dissolving each component. The solvent preferably contains water and is more preferably made of water alone. Further, the solvent may also be a mixed solvent of water and an organic solvent in order to disperse or dissolve each component. In this case, examples of an organic solvent to be used herein include water-miscible organic solvents such as acetone, acetonitrile, ethanol, methanol, isopropanol, glycerin, ethylene glycol, and propylene glycol. Moreover, these organic solvents may be used without mixing with water to disperse or dissolve each component, and then mixed with water. These organic solvents may be used singly or in combinations of two or more thereof.

Water preferably contains residues in an amount as low as possible from the viewpoint of preventing contamination of the polished object and the inhibition of the action of other components. For example, water, in which the total content of transition metal ions is 100 ppb or less, is preferable. Here, the purity of water can be increased by, for example, operation such as removal of residue ions with an ion exchange resin, removal of foreign matter with a filter, distillation, or the like. Specifically, for example, the use of deionized water (ion exchanged water), pure water, ultrapure water, distilled water or the like is preferable.

<Other Additives>

The composition for surface treatment according to an embodiment of the present invention may contain another additive in an arbitrary proportion as necessary to such an extent that the effects of the present invention are not impaired. However, since components other than the essential components of the composition for surface treatment according to an embodiment of the present invention can cause the presence of foreign matter (residues), no addition of such an additive is desired as far as possible. Therefore, the amount thereof to be added is preferably as low as possible. Examples of other additives include an antiseptic agent, dissolved gas, a reducing agent, an oxidizing agent, and a pH adjusting agent.

In order to further improve the effect of removing foreign matter, the composition for surface treatment of the present invention preferably contains substantially no abrasive grains. Here, the expression, “contains substantially no abrasive grains” refers to a case in which the content of abrasive grains with respect to the entire composition for surface treatment is 0.01 mass % or less. More preferably, the composition for surface treatment of the present invention contains no abrasive grain (the content of abrasive grains with respect to the entire composition for surface treatment is 0 mass %).

<pH of Composition for Surface Treatment>

The pH of the composition for surface treatment according to the present invention is not particularly limited, but is preferably 2.0 or more and 12.0 or less.

Furthermore, the pH of the composition for surface treatment has more preferably a pH of 2.0 or more and less than 3.5, or 7.0 or more and 12.0 or less, and further preferably has a pH of 2.0 or more and less than 3.5, or more than 7.0 and 9.0 or less. These pH ranges are particularly suitable for a case in which an object to be polished containing silicon oxide is subjected to the CMP step using a polishing composition containing cerium oxide as abrasive grains, followed by surface treatment.

When the composition for surface treatment has a pH of 3.5 or more and 7.0 or less, the proportion of trivalent cerium oxide increases, resulting in a condition where cerium oxide is easily bound to the surface of silicon oxide contained in a polished object. Specifically, when the composition for surface treatment has a pH of 3.5 or more and 7.0 or less, residues on a surface of a polished object tends to increase. Hence, an embodiment wherein the composition for surface treatment has a pH of 2.0 or more and less than 3.5 or more than 7.0 and 9.0 or less is a further preferable embodiment.

The pH value of the composition for surface treatment can be adjusted using a pH adjusting agent.

The pH adjusting agent is not particularly limited, and known pH adjusting agents that are used in the field of the composition for surface treatment can be used, and a known acid, base, or a salt thereof and the like can be used. Examples of a pH adjusting agent include organic acids, for example, carboxylic acids such as formic acid, acetic acid, propionic acid, butyric acid, valeric acid, caproic acid, enanthic acid, caprylic acid, pelargonic acid, capric acid, lauric acid, myristic acid, palmitic acid, margaric acid, stearic acid, oleic acid, linoleic acid, linolenic acid, arachidonic acid, docosahexaenoic acid, eicosapentaenoic acid, lactic acid, malic acid, citric acid, benzoic acid, phthalic acid, isophthalic acid, terephthalic acid, salicylic acid, gallic acid, mellitic acid, cinnamic acid, oxalic acid, malonic acid, succinic acid, glutaric acid, adipic acid, fumaric acid, maleic acid, aconitic acid, amino acid, and anthranilic acid, sulfonic acid and organic sulfonic acid; inorganic acids such as nitric acid, carbonic acid, hydrochloric acid, phosphoric acid, hypophosphorous acid, phosphorous acid, phosphoric acid, boric acid, hydrofluoric acid, orthophosphoric acid, pyrophosphoric acid, polyphosphoric acid, metaphosphatic acid, and hexametaphosphoric acid; hydroxides of alkali metal such as potassium hydroxide (KOH); hydroxides of group 2 elements; ammonia (ammonium hydroxide); and organic bases such as a quaternary ammonium hydroxide compound.

As the pH adjusting agent, a synthetic product thereof may be used and a commercial product thereof may also be used. Further, these pH adjusting agents may be used singly or in combinations of two or more thereof.

The content of the pH adjusting agent in the composition for surface treatment may be appropriately selected from such a content leading to a desired pH value of the composition for surface treatment.

Note that as the pH of the composition for surface treatment, a vale measured by the method described in the Examples is employed.

<Method for Producing Composition for Surface Treatment>

Regarding the method for producing the composition for surface treatment of the present invention, for example, the composition can be obtained by stirring and mixing water, a water-soluble polymer, and if necessary other components. The temperature at which each component is mixed is not particularly limited, but is preferably 10° C. or higher and 40° C. or lower, and heating may also be performed to increase the rate of dissolution. Further, the mixing time is also not particularly limited.

<Surface Treatment Method>

Another embodiment of the present invention is a surface treatment method comprising surface-treating a polished object using the above composition for surface treatment. The term “surface treatment method” used herein refers to a method for reducing a residue on a surface of a polished object, and is a cleaning method in a broad term.

With the use of the surface treatment method according to an embodiment of the present invention, residues remaining on a surface of a polished object can be sufficiently removed. Specifically, according to another embodiment of the present invention, provided is a method for reducing a residue on a surface of a polished object, comprising surface-treating a polished object using the above composition for surface treatment.

The surface treatment method according to an embodiment of the present invention is performed by a method that involves bringing the composition for surface treatment according to the present invention into direct contact with a polished object.

Examples of the surface treatment method mainly include (I) a method based on rinse polishing treatment, and (II) a method based on cleaning treatment. Specifically, according to an embodiment of the present invention, the above surface treatment is preferably performed by rinse polishing treatment or cleaning treatment. Rinse polishing treatment and cleaning treatment are performed for removing foreign matter on a surface of a polished object (particles, metallic contamination, organic residues, pad debris etc.), so as to obtain a clean surface. (I) and (II) above are described as follows.

(I) Rinse Polishing Treatment

The composition for surface treatment according to the present invention is suitably used in rinse polishing treatment. Specifically, the composition for surface treatment according to an embodiment of the present invention can be preferably used as a rinse polishing composition. The rinse polishing treatment is performed on a platen (turn table platen) with a polishing pad attached thereto, after final polishing (finish polishing) of an object to be polished, in order to remove foreign matter on a surface of an object to be polished. At this time, the composition for surface treatment according to the present invention is brought into direct contact with the polished object, thereby performing rinse polishing treatment. As a result, foreign matter on the surface of the polished object is removed by frictional force (physical action) applied by the polishing pad and chemical action applied by the composition for surface treatment. Of foreign matter, particularly particles and organic residues are easily removed by physical action. Therefore, in the rinse polishing treatment, through the use of friction with the polishing pad on the platen, particles and organic residues can be effectively removed.

Specifically, the terms “rinse polishing treatment”, “rinse polishing method” and “rinse polishing step” used herein refer to, treatment, a method and a step of reducing residues on a surface of an object to be subjected to surface treatment with the use of a polishing pad, respectively.

Specifically, the rinse polishing treatment can be performed by placing, after the polishing step, the surface of the polished object on a platen of a polishing apparatus, bringing the polishing pad and the polished semiconductor substrate into contact with each other, and then sliding the polished object and the polishing pad relative to each other while feeding the composition for surface treatment to the contact portion.

As a polishing apparatus, it is possible to use a general polishing apparatus including a holder for holding an object to be polished and a motor or the like having a changeable rotational speed fitted thereto, and a platen to which a polishing pad (polishing cloth) can be attached.

The rinse polishing treatment can also be performed using any of a one-side polishing apparatus and a double-side polishing apparatus. Further, the above polishing apparatus is preferably provided with, in addition to a discharge nozzle for discharging the polishing composition, a discharge nozzle for discharging the composition for surface treatment. Operation conditions for rinse polishing treatment of the polishing apparatus are not particularly limited, and can be appropriately set by persons skilled in the art.

As the polishing pad, a general nonwoven fabric, polyurethane, a porous fluororesin, or the like can be used without any particular limitation. The polishing pad is preferably grooved such that a composition for surface treatment can be stored therein.

Rinse polishing conditions are also not particularly limited. For example, the rotational speed of a platen, and the rotational speed of a head (carrier) are each preferably 10 rpm (0.17 s⁻¹) or more and 100 rpm (1.67 s⁻¹) or less, and pressure (polishing pressure) to be applied to a polished object is preferably 0.5 psi (3.4 kPa) or more and 10 psi (68.9 kPa) or less. A method for feeding the composition for surface treatment to a polishing pad is also not particularly limited. For example, a method for continuously feeding the composition using a pump or the like (discarded after single use) is employed. The feed rate is not limited, but a surface of the polishing pad is preferably covered all the time with the composition for surface treatment, and is preferably 10 mL/minute or more and 5000 mL/minute or less. The rinse polishing time is not particularly limited, either. However, the time is preferably 5 or more seconds and 180 or less seconds.

After rinse polishing treatment using the composition for surface treatment according to an embodiment of the present invention, the polished object (object to be subjected to surface treatment) is preferably lifted up and removed while being applied with the composition for surface treatment according to an embodiment of the present invention.

(II) Cleaning Treatment

The composition for surface treatment according to the present invention may also be used in cleaning treatment. Specifically, the composition for surface treatment according to an embodiment of the present invention can be preferably used as a cleaning composition. Cleaning treatment is preferably performed for removing foreign matter on a surface of a polished object (object to be cleaned) after final polishing (finish polishing) of an object to be polished, after the above rinse polishing treatment, or after another rinse polishing treatment using a rinse polishing composition other than the composition for surface treatment of the present invention. Note that the cleaning treatment and the above rinse polishing treatment are classified based on locations where these treatments are performed. The cleaning treatment is preferably surface treatment that is performed at a location not on a platen and is performed after removal of the polished object from the platen. In such cleaning treatment, the composition for surface treatment according to the present invention is brought into direct contact with a polished object so as to be able to remove foreign matter on the surface of the object.

Examples of a method for performing cleaning treatment include (i) a method that involves bringing a cleaning brush into contact with one side or both sides of a polished object while holding the polished object, and then running the cleaning brush over the surface of an object to be cleaned while feeding the composition for surface treatment to the contact portion, and (ii) a method (dipping mode) that involves immersing a polished object in the composition for surface treatment, and then performing ultrasonic treatment or stirring. With the use of such a method, foreign matter on a surface of a polished object is removed by frictional force applied by a cleaning brush or mechanical force that is generated by ultrasonic treatment or stirring, and chemical action applied by the composition for surface treatment.

In the above method (i), a method for bringing the composition for surface treatment into contact with a polished object, is not particularly limited, and examples thereof include a spinning mode whereby a polished object is rotated at a high speed while the composition for surface treatment is poured from a nozzle onto the polished object, and the spraying mode whereby the composition for surface treatment is sprayed to a polished object to clean the object.

From the viewpoint of being capable of more efficiently performing decontamination within a short time, the cleaning treatment preferably employs the spinning mode or the spraying mode, and the same further preferably employs the spinning mode.

Examples of an apparatus for performing such cleaning treatment include a batch-type cleaning apparatus by which a plurality of polished objects housed in a cassette are surface-treated simultaneously, and a single wafer processing-type cleaning apparatus, by which, a sheet of a polished object is held by a holder for surface treatment. From the viewpoint of shortening of cleaning time or the like, a method that involves the use of a single wafer processing-type cleaning apparatus is preferable.

Furthermore, an example of an apparatus for performing cleaning treatment is a polishing apparatus provided with a cleaning facility, by which a polished object is scrubbed with a cleaning brush after the polished object is removed from a platen. Through the use of such polishing apparatuses, cleaning treatment can be more efficiently performed for polished objects.

As such a polishing apparatus, it is possible to use a general polishing apparatus including a holder for holding a polished object, a motor having a changeable rotational speed, a cleaning brush, and the like. As a polishing apparatus, any of a one-side polishing apparatus and a double-side polishing apparatus may also be used. Note that when a rinse polishing step is performed after the CMP step, it is more efficient and preferable to perform the cleaning treatment using the same apparatus as that in the rinse polishing step.

The cleaning brush is not particularly limited, but is preferably a resin brush (brush made of resin). The material of the resin brush is not particularly limited, but is preferably PVA (polyvinyl alcohol). The cleaning brush is more preferably a PVA sponge (sponge made of PVA).

Cleaning conditions are also not particularly limited, and can be appropriately set in accordance with the type of an object to be subjected to surface treatment (polished object), as well as the type and the amount of residues to be removed. For example, the rotational speed of the cleaning brush is preferably 10 rpm (0.17 s⁻¹) or more and 200 rpm (3.33 s⁻¹) or less, and the rotational speed of an object to be cleaned is preferably 10 rpm (0.17 s⁻¹) or more and 100 rpm (1.67 s⁻¹) or less. A method for feeding the composition for surface treatment to a polishing pad is also not particularly limited. For example, a method for continuously feeding the composition using a pump or the like (discarded after single use) is employed. The feed rate is not limited, but a cleaning brush and a surface of an object to be cleaned are preferably covered all the time with the composition for surface treatment, and is preferably 10 mL/minute or more and 5000 mL/minute or less. The cleaning time is also not particularly limited, but the time for a step using the composition for surface treatment according to an embodiment of the present invention is preferably 5 or more seconds and 180 or less seconds. When the cleaning time is within such range, foreign matter can be more effectively removed.

The temperature of the composition for surface treatment upon cleaning is not particularly limited, and may be generally room temperature. As long as the performance is not impaired, the temperature may also be increased to about 40° C. or higher and 70° C. or lower.

In the above method (ii), conditions for a cleaning method that involves immersion are not particularly limited, and a known technique can be used.

Before surface treatment is performed according to the above method (I) or (II), cleaning with water may also be performed.

(Post-Cleaning Treatment)

Further, a surface treatment method preferably involves further cleaning of the polished object by cleaning treatment after surface treatment of (I) or (II) above using the composition for surface treatment according to an embodiment of the present invention. This “cleaning treatment” used herein is referred to as post-cleaning treatment. Examples of the post-cleaning treatment include, but are not particularly limited to, a method that involves simply pouring water over an object to be subjected to surface treatment (discarded after single use), and a method that involves simply immersing an object to be subjected to surface treatment in water. Further examples thereof include a method that involves, in the manner same as in surface treatment according to the above-described method (II), bringing a cleaning brush into contact with the one side or both sides of an object to be subjected to surface treatment into contact, while holding the object to be subjected to surface treatment, and then scrubbing the surface(s) of the object to be subjected to surface treatment with the cleaning brush while feeding water to the contact portion, and a method (dipping mode) that involves immersing an object to be subjected to surface treatment in water, and then performing ultrasonic treatment and stirring. Of these methods, the preferable method involves bringing a cleaning brush into contact with the one side or both sides of an object to be subjected to surface treatment while holding the object, and then scrubbing the surface(s) of the object to be subjected to surface treatment while feeding water to the contact portion. Note that regarding apparatuses and conditions of the post-cleaning treatment, the description of the surface treatment of (II) above can be referred to. Here, as water to be used for the post-cleaning treatment, particularly deionized water is preferably used.

Surface treatment is performed using the composition for surface treatment according to an embodiment of the present invention, so that residues are exceedingly easily removed. Accordingly, surface treatment is performed using the composition for surface treatment according to the surface treatment of an embodiment of the present invention, and then further cleaning treatment is performed using water, so that residues are removed extremely well.

Further, a polished object (object to be subjected to surface treatment) after surface treatment or after post-cleaning is preferably dried by removing water droplets adhered onto the surface(s) using a spin dryer or the like. Moreover, the surface(s) of an object to be subjected to surface treatment may also be dried by air-blow drying.

<Method for Producing Semiconductor Substrate>

The surface treatment method according to an embodiment of the present invention is suitably applied when a polished object is a polished semiconductor substrate. Specifically, according to another embodiment of the present invention, a method for producing a semiconductor substrate is also provided, wherein a polished object is a polished semiconductor substrate, and residues on the surface of the polished semiconductor substrate are reduced by the above surface treatment method.

Detailed descriptions of a semiconductor substrate, to which such a production method is applied, are the same as given for a polished object that is surface-treated with the above composition for surface treatment.

Further the method for producing a semiconductor substrate is not particularly limited, as long as it comprises a step of surface-treating (surface treatment step) a surface of a polished semiconductor substrate using the composition for surface treatment according to an embodiment of the present invention. An example of such a production method is a method having a polishing step and a cleaning step for forming a polished semiconductor substrate. Another example thereof is a method having a rinse polishing step between a polishing step and a cleaning step, in addition to the polishing step and the cleaning step. Each of these steps is as described below.

[Polishing Step]

A polishing step that can be included in a method for producing a semiconductor substrate is a step for polishing a semiconductor substrate, so as to form a polished semiconductor substrate.

The polishing step is not particularly limited, as long as it is a step for polishing a semiconductor substrate, but the polishing step is preferably a Chemical Mechanical Polishing (CMP) step. Further, the polishing step may comprise a single process or a plurality of processes. Examples of the polishing step comprising a plurality of processes include a polishing step wherein a preliminary polishing process (rough polishing process) is performed and then a finish polishing process is performed, and a polishing step wherein a primary polishing process is performed, a secondary polishing process is performed once or two or more times, and then a finish polishing process is performed. The surface treatment step using the composition for surface treatment according to the present invention is preferably performed after the above finish polishing process.

As the polishing composition, a known polishing composition can be appropriately used in accordance with the property of a semiconductor substrate. Examples of the polishing composition that can be preferably used include, but are not particularly limited to, polishing compositions containing abrasive grains, dispersing medium, and acid. A specific example of such a polishing composition is a polishing composition containing cerium oxide, maleic acid, polyacrylic acid, and water.

As a polishing apparatus, it is possible to use a general polishing apparatus including a holder for holding an object to be polished and a motor or the like having a changeable rotational speed fitted thereto, and a platen to which a polishing pad (polishing cloth) can be attached. As a polishing apparatus, any of a one-side polishing apparatus and a double-side polishing apparatus may also be used.

As the polishing pad, a general nonwoven fabric, polyurethane, a porous fluororesin, or the like can be used without any particular limitation. The polishing pad is preferably grooved such that a polishing liquid can be stored therein.

Polishing conditions are also not particularly limited, either. For example, the rotational speed of a platen and the rotational speed of a head are each preferably 10 rpm (0.17 s⁻¹) or more and 100 rpm (1.67 s⁻¹) or less, and the pressure (polishing pressure) applied to an object to be polished is preferably 0.5 psi (3.4 kPa) or more and 10 psi (68.9 kPa) or less. A method for feeding a polishing composition to a polishing pad is not particularly limited, either. For example, a method that involves feeding a polishing composition continuously using a pump or the like can be employed (discarded after single use). The feed rate is not limited, but a surface of the polishing pad is preferably covered all the time with the polishing composition, and it is preferably 10 mL/minute or more and 5000 mL/minute or less. The polishing time is also not particularly limited, either. However, for the step of using the polishing composition, it is preferably 5 seconds or more and 180 seconds or less.

[Surface Treatment Step]

The surface treatment step refers to a step of reducing residues on a surface of a polished object using the composition for surface treatment according to the present invention. In a method for producing a semiconductor substrate, after a rinse polishing step, a cleaning step as the surface treatment step may be performed, the rinse polishing step alone or the cleaning step alone may be performed.

(Rinse Polishing Step)

The rinse polishing step may be provided between the polishing step and the cleaning step in the method for producing a semiconductor substrate. The rinse polishing step is a step for reducing foreign matter on a surface of a polished object (polished semiconductor substrate) by the surface treatment method (rinse polishing treatment method) according to an embodiment of the present invention.

Detailed descriptions of a rinse polishing method employed in the rinse polishing step are as given for the above rinse polishing treatment.

(Cleaning Step)

The cleaning step may be provided following the polishing step or the rinse polishing step in a method for producing a semiconductor substrate. The cleaning step is a step for reducing foreign matter on a surface of a polished object (polished semiconductor substrate) by the surface treatment method (cleaning method) according to an embodiment of the present invention.

Detailed descriptions for a cleaning method employed in the cleaning step are as given for the above cleaning method.

The embodiments of the present invention are described in detail above, but are explanatory and illustrative only, and are not limited. The scope of the present invention should be obviously construed on the basis of the attached claims.

[1] A composition for surface treatment for use in reducing a residue on a surface of a polished object, containing:

a solvent and a water-soluble polymer, wherein

an adsorption amount of the water-soluble polymer adsorbed to a quartz crystal microbalance electrode is 100 ng/cm² or more and 600 ng/cm² or less per unit area of the quartz crystal microbalance electrode.

[2] The composition for surface treatment according to [1], wherein the water-soluble polymer is a nonionic water-soluble polymer.

[3] The composition for surface treatment according to [1] or [2], wherein the water-soluble polymer has a solubility parameter of 11 or more and 15 or less.

[4] The composition for surface treatment according to any one of [1] to [3], wherein the water-soluble polymer is poly-N-vinylacetamide.

[5] The composition for surface treatment according to any one of [1] to [4], wherein the composition for surface treatment has a pH of 2.0 or more and less than 3.5, or 7.0 or more and 12.0 or less.

[6] The composition for surface treatment according to any one of [1] to [5], comprising substantially no abrasive grains.

[7] The composition for surface treatment according to any one of [1] to [6], wherein the polished object contains a hydrophilic material having a contact angle with respect to water of less than 50° and a hydrophobic material having a contact angle with respect to water of 50° or more.

[8] The composition for surface treatment according to [7], wherein the hydrophilic material is silicon oxide and the hydrophobic material is polycrystalline silicon.

[9] The composition for surface treatment according to any one of [1] to [8], wherein

a SiO₂ electrode and an Au electrode are used as the quartz crystal microbalance electrode,

the adsorption amount of the water-soluble polymer adsorbed to the SiO₂ electrode is 100 ng/cm² or more and 600 ng/cm² or less per unit area of the SiO₂ electrode, and

the adsorption amount of the water-soluble polymer adsorbed to the Au electrode is 100 ng/cm² or more and 600 ng/cm² or less per unit area of the Au electrode.

[10] A surface treatment method, comprising surface-treating a polished object using the composition for surface treatment according to any one of [1] to [9] to reduce a residue on a surface of the polished object.

[11] The surface treatment method according to [10], wherein the surface treatment is performed by rinse polishing treatment or cleaning treatment.

[12] A method for producing a semiconductor substrate, comprising

reducing a residue on a surface of a polished semiconductor substrate by the surface treatment method according to [10] or [11], wherein

the polished object is the polished semiconductor substrate.

### EXAMPLES

The present invention will be described in more detail using the following Examples and Comparative Examples, but the technical scope of the present invention is not limited to only the following Examples. Note that unless otherwise specified, and “part(s)” refer to “mass %” and “parts by mass”, respectively. Further, in the following Examples, unless otherwise specified, operation was performed under conditions of room temperature (25° C.)/relative humidity of 40% RH or more and 50% RH or less.

[Preparation of Water-Soluble Polymer and Surfactant]

The following water-soluble polymers and surfactants were prepared. Note that the SP value of each water-soluble polymer was calculated by the Fedors method (Literature: R. F. Fedors, Polym. Eng. Sci., 14[2]147(1974)):

Poly-N-vinylacetamide (PNVA), Mw=50,000: manufactured by SHOWA DENKO K.K., Product number: PNVA GE101-107, SP value 13.9

Poly-N-vinylacetamide, Mw=300,000: manufactured by SHOWA DENKO K.K., Product number: PNVA GE191-104, SP value 12.6

Poly-N-vinylacetamide, Mw=900,000: manufactured by SHOWA DENKO K.K., Product number: PNVA GE191-107, SP value 11.0

Hydroxyethylcellulose (HEC), Mw=1,200,000: manufactured by SUMITOMO SEIKA CHEMICALS CO., LTD., Product number: HEC, SP value 14.8

Polyvinyl alcohol (PVA), Mw=10,000: manufactured by JAPAN VAM & POVAL CO., LTD., Product number: JMR-10HH, SP value 17.3

Polyglycerol alkyl ether (PGLE), Mw=2,000: manufactured by DAICEL CORPORATION, Product number: Celmoris (registered trademark) B044, SP value 19.0

Polymethyl methacrylate (PMMA): SP value 9.1

Polyurethane (PU): SP value 10.0

Acrylic acid/sulfonic acid copolymer, Mw=12,000, SP value 15.3

Ammonium lauryl sulfate, Mw=283.4: manufactured by Kao Corporation, Product number: Emal (registered trademark) AD-25R, SP value 9.6.

The weight-average molecular weights of the above water-soluble polymers were measured by the following method.

[Measurement of Weight-Average Molecular Weight (Mw) of Water-Soluble Polymer]

As the weight-average molecular weights (Mw) of the water-soluble polymers, the values of the weight-average molecular weights (in terms of polyethylene glycol) measured by gel permeation chromatography (GPC) were used. The weight-average molecular weights were measured using the following apparatuses and conditions:

GPC apparatus: manufactured by SHIMADZU CORPORATION

Model: Prominence+ELSD detector (ELSD-LTII)

Column: VP-ODS (manufactured by SHIMADZU CORPORATION)

Mobile phase A: MeOH
B: Acetic acid 1% aqueous solution

Flow rate: 1 mL/min

Detector: ELSD temp. 40° C., Gain 8, N₂GAS 350 kPa

Oven temperature: 40° C.

Amount injected: 40 μL.

[Measurement of pH of Composition for Surface Treatment]

The pH of the composition for surface treatment (liquid temperature: 25° C.) was confirmed using a pH meter (manufactured by HORIBA, Ltd., Product name: LAQUA (registered trademark)).

[Preparation of Composition for Surface Treatment]

### Example 1

Poly-N-vinylacetamide (Mw=50,000) as a water-soluble polymer, water as a solvent (deionized water), and nitric acid as a pH adjusting agent were mixed and stirred at 25° C. for 5 minutes, thereby preparing composition 1 for surface treatment.

Here, the content of the water-soluble polymer was 0.075 mass % with respect to the total amount of composition 1 for surface treatment, and the content of the pH adjusting agent was determined so that the pH of composition 1 for surface treatment was 2.0.

### Examples 2 to 7, Comparative Examples 1 and 2

Except for changing the contents of the water-soluble polymer to values described in Table 1 below, compositions 2 to 7, and 19 and 20 for surface treatment were prepared in the same manner as in Example 1.

### Examples 8 to 13

Except for changing pHs as described in Table 1 below, compositions 8 to 13 for surface treatment were prepared in the same manner as in Example 7. Note that a pH adjusting agent used in Example 13 was ammonia, and nitric acid was used in Examples other than Example 13.

### Examples 14 and 15

Except for changing water-soluble polymers as described in Table 1 below, compositions 14 and 15 for surface treatment were prepared in the same manner as in Example 2.

### Example 16

Hydroxyethyl cellulose (Mw=1,200,000) as a water-soluble polymer, water (deionized water) as a solvent, and ammonia as a pH adjusting agent were mixed, thereby preparing composition 16 for surface treatment.

Here, the content of the water-soluble polymer was 0.016 mass % with respect to the total amount of composition 16 for surface treatment, and the content of the pH adjusting agent was determined so that the pH of composition 16 for surface treatment was 8.5.

### Example 17

Polyvinyl alcohol (Mw=10,000) as a water-soluble polymer, water (deionized water) as a solvent, and nitric acid as a pH adjusting agent were mixed, thereby preparing composition 17 for surface treatment.

Here, the content of the water-soluble polymer was 0.1 mass % with respect to the total amount of composition 17 for surface treatment, and the content of the pH adjusting agent was determined so that the pH of composition 17 for surface treatment was 3.0.

### Example 18

Except for adjusting the pH to 9.0 using ammonia as a pH adjusting agent, composition 18 for surface treatment was prepared in the same manner as in Example 17.

### Comparative Examples 3 to 5

Except for changing the type and the concentration of a water-soluble polymer as described in Table 1 below, compositions 21 to 23 for surface treatment were prepared in the same manner as in Example 1.

### Comparative Example 6

Composition 24 for surface treatment was prepared by mixing acrylic acid/sulfonic acid copolymer (Mw=12,000) as a water-soluble polymer, water (deionized water) as a solvent, and nitric acid as a pH adjusting agent.

Here, the content of the water-soluble polymer was 0.01 mass % with respect to the total amount of composition 24 for surface treatment, and the content of the pH adjusting agent was determined so that the pH of composition 24 for surface treatment was 2.0.

### Comparative Example 7

Composition 25 for surface treatment was prepared by mixing ammonium lauryl sulfate (Mw=283.4) as a surfactant, water (deionized water) as a solvent, and nitric acid as a pH adjusting agent.

Here, the content of a surfactant was 0.06 mass % with respect to the total amount of composition 25 for surface treatment, and the content of the pH adjusting agent was determined so that the pH of composition 25 for surface treatment was 2.0.

[Adsorption Amount of Water-Soluble Polymer]

The adsorption amount of the water-soluble polymer contained in each composition for surface treatment, and adsorbed to a quartz crystal microbalance electrode was measured.

More specifically, QCM-D instrument, Q-Sense Pro (manufactured by Biolin Scientic), was used as a measurement apparatus. Pure water (180 μL) was set in the apparatus and stabilized at 25° C. Subsequently, each composition for surface treatment was run at a flow rate of 20 μL/minute for 5 minutes, and then the adsorption amount of a water-soluble polymer (unit: ng/cm²) per unit area of each electrode was measured.

As electrodes, a SiO₂ electrode and an Au electrode were used. The adsorption amount of a water-soluble polymer adsorbed to the SiO₂ electrode is an indicator representing the adsorption amount of the water-soluble polymer adsorbed to a hydrophilic material contained in a polished object, and the adsorption amount of a water-soluble polymer adsorbed to the Au electrode is an indicator representing the adsorption amount of the water-soluble polymer adsorbed to a hydrophobic material contained in a polished object.

[Preparation of Polished Object]

Polished objects were prepared after polishing in the following chemical mechanical polishing (CMP) step.

(CMP Step)

As objects to be polished, a silicon wafer (TEOS substrate) (300 mm, blanket wafer, manufactured by ADVANTEC CO., LTD.) having a surface with a 10000 Å thick TEOS film formed thereon, and a polycrystalline silicon wafer (300 mm, manufactured by Advanced Materials Technology, INC.) were prepared.

The above-prepared TEOS substrate and polycrystalline silicon wafer were polished using 1 mass % of a polishing composition (composition; cerium oxide (average primary particle size of 30 nm, average secondary particle size of 60 nm), 0.3 mass % of maleic acid, 1 mass % of polyacrylic acid, and a solvent: water) under following conditions:

<Polishing Apparatus and Polishing Conditions>

Polishing apparatus: manufactured by Ebara Corporation, FREX300E

Polishing pad: manufactured by Fujibo Holdings, Inc., foamed polyurethane pad H800

Conditioner (dresser): nylon brush (A165, manufactured by 3M Company)

Polishing pressure: 2.0 psi (1 psi=6894.76 Pa, the same applies to the following)

Rotational speed of platen: 80 rpm

Rotational speed of head: 80 rpm

Feed of polishing composition: free flowing

Feed rate of polishing composition: 200 mL/minute

Polishing time: 30 seconds.

(Rinse Polishing)

After polishing of the surface of each object to be polished in the above CMP step, the polished object was removed from the platen. Next, within the same polishing apparatus, the polished object was set on another platen, and then under the following conditions, the surface of the polished object was subjected to rinse polishing treatment using the compositions for surface treatment prepared in Examples 1 to 18 above and the compositions for surface treatment prepared in Comparative Examples 1 to 7 above:

<Rinse Polishing Apparatus and Rinse Polishing Conditions>

Polishing pressure: 1.0 psi

Rotational speed of platen: 60 rpm

Rotational speed of head: 60 rpm

Feed of polishing composition: free flowing

Feed rate of composition for surface treatment: 300 mL/minute

Polishing time: 60 seconds.

After rinse polishing treatment, the surface of a substrate was subjected to brush cleaning for 60 seconds using deionized water, thereby obtaining a rinse-polished object that had been rinsed and polished.

[Evaluation]

(Measurement of the Number of Residues)

The number of residues on the surface of the polished object that had been subjected to rinse polishing treatment was evaluated using an optical inspector Surfscan (registered trademark) SP5 (manufactured by KLA-Tencor Japan Ltd.). The number of residues exceeding a diameter of 37 μm was counted in the case of the TEOS substrate, and the number of residues exceeding a diameter of 57 μm was counted in the case of the polycrystalline silicon wafer.

Evaluation results are described in Table 1 below.

TABLE 1

| | Composition for surface treatment | | | | | | | SiO₂ | Au | | |
|---|---|---|---|---|---|---|---|---|---|---|---|
| | | Water-soluble polymer | | | | | | electrode | electrode | Number of | |
| | | | | | | Concen- | | Adsorption | Adsorption | residues | |
| | | | | | SP | tration | | amount | amount | | poly- |
| | No. | Type | Mw | Ionicity | value | (mass %) | pH | (ng/cm²) | (ng/cm²) | TEOS | Si |
| Example 1 | 1 | Poly-N-vinylacetamide | 50000 | Nonionic | 13.9 | 0.075 | 2.0 | 255 | 228 | 7343 | 3645 |
| Example 2 | 2 | Poly-N-vinylacetamide | 50000 | Nonionic | 13.9 | 0.1 | 2.0 | 263 | 240 | 8198 | 3959 |
| Example 3 | 3 | Poly-N-vinylacetamide | 50000 | Nonionic | 13.9 | 0.15 | 2.0 | 288 | 250 | 6932 | 2685 |
| Example 4 | 4 | Poly-N-vinylacetamide | 50000 | Nonionic | 13.9 | 0.2 | 2.0 | 316 | 308 | 8052 | 2889 |
| Example 5 | 5 | Poly-N-vinylacetamide | 50000 | Nonionic | 13.9 | 0.3 | 2.0 | 473 | 346 | 8419 | 3409 |
| Example 6 | 6 | Poly-N-vinylacetamide | 50000 | Nonionic | 13.9 | 0.5 | 2.0 | 526 | 411 | 8934 | 3358 |
| Example 7 | 7 | Poly-N-vinylacetamide | 50000 | Nonionic | 13.9 | 0.125 | 2.0 | 272 | 245 | 7715 | 3396 |
| Example 8 | 8 | Poly-N-vinylacetamide | 50000 | Nonionic | 13.9 | 0.125 | 3.3 | 211 | 238 | 8233 | 3218 |
| Example 9 | 9 | Poly-N-vinylacetamide | 50000 | Nonionic | 13.9 | 0.125 | 3.5 | 239 | 265 | 9764 | 3499 |
| Example 10 | 10 | Poly-N-vinylacetamide | 50000 | Nonionic | 13.9 | 0.125 | 5.0 | 226 | 244 | 10058 | 3267 |
| Example 11 | 11 | Poly-N-vinylacetamide | 50000 | Nonionic | 13.9 | 0.125 | 7.0 | 246 | 228 | 9973 | 3154 |
| Example 12 | 12 | Poly-N-vinylacetamide | 50000 | Nonionic | 13.9 | 0.125 | 7.6 | 229 | 271 | 8659 | 3308 |
| Example 13 | 13 | Poly-N-vinylacetamide | 50000 | Nonionic | 13.9 | 0.125 | 9.0 | 213 | 221 | 7035 | 3056 |
| Example 14 | 14 | Poly-N-vinylacetamide | 300000 | Nonionic | 12.6 | 0.1 | 2.0 | 299 | 338 | 6098 | 2765 |
| Example 15 | 15 | Poly-N-vinylacetamide | 900000 | Nonionic | 11.0 | 0.1 | 2.0 | 315 | 428 | 7025 | 3001 |
| Example 16 | 16 | Hydroxyethylcellulose | 1200000 | Nonionic | 14.8 | 0.016 | 8.5 | 217 | 529 | 8096 | 4514 |
| Example 17 | 17 | Polyvinyl alcohol | 10000 | Nonionic | 17.3 | 0.1 | 3.0 | 118 | 150 | 8865 | 4017 |
| Example 18 | 18 | Polyvinyl alcohol | 10000 | Nonionic | 17.3 | 0.1 | 9.0 | 130 | 166 | 8024 | 3653 |
| Comparative | 19 | Poly-N-vinylacetamide | 50000 | Nonionic | 13.9 | 0.025 | 2.0 | 68 | 55 | 10552 | 6697 |
| Example 1 | | | | | | | | | | | |
| Comparative | 20 | Poly-N-vinylacetamide | 50000 | Nonionic | 13.9 | 0.75 | 2.0 | 726 | 698 | 11637 | 7725 |
| Example 2 | | | | | | | | | | | |
| Comparative | 21 | Polyglycerol alkyl ether | 2000 | Nonionic | 19.0 | 0.1 | 2.0 | 27 | 94 | 15512 | 9974 |
| Example 3 | | | | | | | | | | | |
| Comparative | 22 | Polymethyl methacrylate | — | Nonionic | 9.1 | 0.1 | 2.0 | 776 | 935 | 21050 | 20698 |
| Example 4 | | | | | | | | | | | |
| Comparative | 23 | Polyurethane | — | Nonionic | 10.0 | 0.21 | 2.0 | 853 | 1015 | 19975 | 23254 |
| Example 5 | | | | | | | | | | | |
| Comparative | 24 | Acrylic acid/ | 12000 | Anionic | 15.3 | 0.01 | 2.0 | 6 | 41 | 14402 | 10354 |
| Example 6 | | sulfonic acid copolymer | | | | | | | | | |
| Comparative | 25 | Ammonium lauryl sulfate | 283.4 | Anionic | 9.6 | 0.06 | 2.0 | 18 | 84 | 12319 | 7687 |
| Example 7 | | | | | | | | | | | |

As is clear from Table 1 above, it was revealed that the use of compositions for surface treatment of Examples can sufficiently remove residues on the TEOS substrate and the polycrystalline silicon wafer, unlike the use of the compositions for surface treatment of Comparative Examples.

The present application is based on the Japanese patent application No. 2021-059480 filed on Mar. 31, 2021, and the disclosed contents thereof is incorporated herein by reference in their entirety.

1. A composition for surface treatment for use in reducing a residue on a surface of a polished object, comprising:
a solvent and a water-soluble polymer, wherein
an adsorption amount of the water-soluble polymer adsorbed to a quartz crystal microbalance electrode is 100 ng/cm² or more and 600 ng/cm² or less per unit area of the quartz crystal microbalance electrode.

2. The composition for surface treatment according to claim 1, wherein the water-soluble polymer is a nonionic water-soluble polymer.

3. The composition for surface treatment according to claim 1, wherein the water-soluble polymer has a solubility parameter of 11 or more and 15 or less.

4. The composition for surface treatment according to claim 1, wherein the water-soluble polymer is poly-N-vinylacetamide.

5. The composition for surface treatment according to claim 1, wherein the composition for surface treatment has a pH of 2.0 or more and less than 3.5, or 7.0 or more and 12.0 or less.

6. The composition for surface treatment according to claim 1, comprising substantially no abrasive grains.

7. The composition for surface treatment according to claim 1, wherein the polished object contains a hydrophilic material having a contact angle with respect to water of less than 50° and a hydrophobic material having a contact angle with respect to water of 50° or more.

8. The composition for surface treatment according to claim 7, wherein the hydrophilic material is silicon oxide and the hydrophobic material is polycrystalline silicon.

9. The composition for surface treatment according to claim 1, wherein
a SiO₂ electrode and an Au electrode are used as the quartz crystal microbalance electrode,
the adsorption amount of the water-soluble polymer adsorbed to the SiO₂ electrode is 100 ng/cm² or more and 600 ng/cm² or less per unit area of the SiO₂ electrode, and
the adsorption amount of the water-soluble polymer adsorbed to the Au electrode is 100 ng/cm² or more and 600 ng/cm² or less per unit area of the Au electrode.

10. A surface treatment method, comprising surface-treating a polished object using the composition for surface treatment according to claim 1 to reduce a residue on a surface of the polished object.

11. The surface treatment method according to claim 10, wherein the surface treatment is performed by rinse polishing treatment or cleaning treatment.

12. A method for producing a semiconductor substrate, comprising
reducing a residue on a surface of a polished semiconductor substrate by the surface treatment method according to claim 10, wherein
the polished object is the polished semiconductor substrate.
